(19) United States
(12) Patent Application Publication
(10) Pub. No.: US 2013/0143416 A1
(43) Pub. Date: Jun. 6, 2013

(54) LASER ABLATION WITH EXTRACTION OF THE ABLATED MATERIAL

(71) Applicant: Shane Norval, Cambridge (GB)

(72) Inventor: Shane Norval, Cambridge (GB)

(73) Assignee: PLASTIC LOGIC LIMITED, Cambridge (GB)

(21) Appl. No.: 13/701,752

(22) PCT Filed: Jun. 3, 2011
(86) PCT No.: PCT/EP2011/059213

§ 371 Date: Feb. 12, 2013

(30) Foreign Application Priority Data
Jun. 4, 2010 (GB) 1009405.0

(51) Int. Cl. H01L 21/263

(52) U.S. Cl. CPC H01L 21/2633
USPC 438/795

(57) ABSTRACT

A technique comprising: using a laser beam to ablate a target surface (2) via projection lens (12) as part of a process of defining one or more elements of one or more electronic devices, wherein the ablating is performed whilst extracting material ablated from the target surface via an extraction device inlet (6) having at least a portion at a level between said target surface (2) and said projection lens (12) and at the level of a plume of ablated material above said target surface.

The present invention relates to a technique for ablating a surface as part of a process for forming one or more electronic elements of an electronic device.

It is known to use laser ablation in the production of organic polymer electronic devices. For example, International Patent Publication No. WO2006/064275 describes the use of laser ablation to pattern an organic semiconductor channel layer for the purpose of reducing crosstalk between thin-film transistors (TFTs) of an array of TFTs for controlling a display medium, such as an electrophoretic medium.

There has been identified the challenge of effectively preventing debris generated by the ablation process negatively affecting the ablation process.

It is an aim of the present invention to meet this challenge.

The present invention provides a method, comprising: using a laser beam to ablate a target surface via a projection lens as part of a process of defining one or more elements of one or more electronic devices, wherein the ablating is performed whilst extracting material ablated from the target surface via an extraction device inlet having at least a portion at a level between said target surface and said projection lens and at the level of a plume of ablated material above said target surface.

In one embodiment, the method further comprises: ablating said target surface whilst directing a flow of gas transversely across said target surface in a direction substantially parallel to the target surface from a gas outlet towards said extraction device inlet.

In one embodiment, the gas outlet is arranged opposite to the extraction device inlet across the ablation image.

In one embodiment, the extraction device inlet and the gas outlet are configured so as to achieve a substantially uniform gas flow velocity across the entire ablation image at the target surface.

In one embodiment, the extraction device inlet extends in a direction perpendicular to the target surface to a height greater than the height of said plume.

In one embodiment, the extraction device inlet extends in a direction perpendicular to the target surface to a height at least 1.6 times greater than the height of said plume.

In one embodiment, the gas outlet includes an array of gas nozzles distributed over a distance greater than the distance to which said ablation image at the target surface extends in a direction perpendicular to said flow of gas.

In one embodiment, the extraction device inlet has at least a portion no less than about 10 mm from the ablation image in a direction parallel to the target surface.

In one embodiment, the extraction device inlet has a bottom edge located no less than about 2 mm above the target surface in a direction perpendicular to the target surface.

An embodiment of the present invention is described in detail herebelow, by way of example only, with reference to the accompanying drawings, in which:

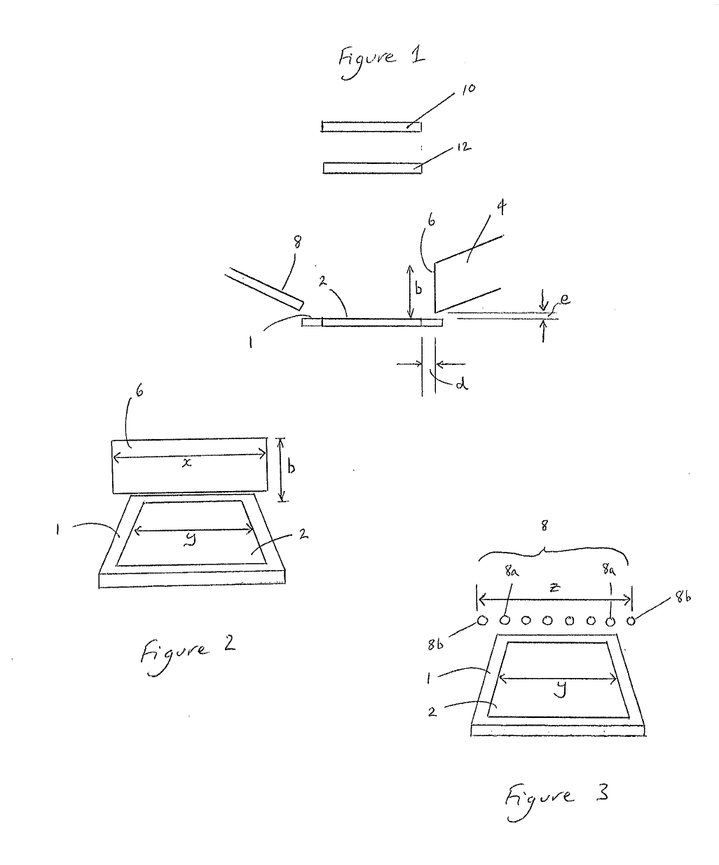

FIG. 1 illustrates the arrangement of an extraction device inlet in relation to an ablated surface and a projection lens in accordance with a first embodiment of the present invention;

FIG. 2 illustrates the configuration of an extraction device inlet in relation to an ablated surface in accordance with an embodiment of the present invention;

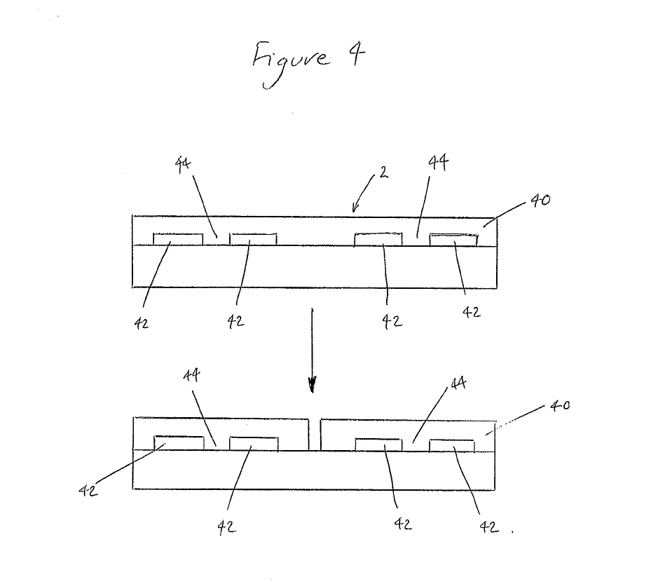

FIG. 3 illustrates an arrangement of gas nozzles for directing a flow of gas over the ablated surface in accordance with an embodiment of the present invention; and

FIG. 4 illustrates an example of a target surface and a patterning process to which a technique in accordance with the present invention is applicable.

With reference to FIGS. 1 to 3, the patterning of a surface by laser ablation involves generating a laser beam at laser apparatus (not shown), directing the laser beam at a mask (not shown) that defines the image to be ablated on the target surface; directing the laser beam from the mask 10 into a projection lens 12, which focuses the mask pattern on the target surface 1 and increases beam intensity at the target surface 1.

A debris extraction system in accordance with an embodiment of the present invention comprises: (a) an extraction device including a duct/tube 4 having a mouth/inlet 6 located at a level between the projection lens and the target surface and having a portion substantially level with where a plume of ablated material forms during ablation. The extraction device inlet 6 is oriented in a direction substantially perpendicularly to the target surface plane. The duct/tube 4 leads to a part (not shown) of the extraction device at which a low pressure/vacuum is mechanically created; The debris extraction system in accordance with an embodiment of the present invention further comprises (b) an array of gas nozzles 8 adjacent to and substantially level with the ablation image 2 at the target surface 1 for directing a flow of an inert gas such as nitrogen gas across the ablation image 2 at the target surface 1 at an angle perpendicular to the target surface 1 and towards the extraction device inlet 6

The extent to which a plume of ablated material extends above the target surface depends on several factors, including: the size of the area that is being ablated; thickness of the layer being ablated; the ablation threshold of the material being ablated; and the fluence of the laser beam used for the ablation.

When the material to be ablated is an organic polymer, the height of the ablation plume is relatively small, and when the material to be ablated is a metal, the height of the ablation plume is relatively large. Also, generally, the higher the fluence of the laser beam, the larger the height of the ablation plume. In this embodiment of the invention, the height of the plume is about 8 mm to 10 mm.

In operation, the combination of the gas nozzle array 8 and the extraction device function to create a flow of inert gas across the ablation image 2 at the target surface 1 during ablation, which flow assists the removal of ablation debris particles from above the target surface 1 and away via the extraction device inlet 6.

The flow of inert gas across the ablation image 2 at the target surface 1 during ablation also serves to prevent harmful contaminants such as oxygen influencing the ablation process.

With particular reference to FIG. 1, the extraction device inlet 6 has a bottom edge located just above the ablation image 2 at the target surface 1 and is located closer to the ablation image 2 at the target surface 1 than the projection lens 12. This configuration serves to better protect the projection lens 12 against the deposition of ablation debris onto the lens 12. Also, the close proximity of the extraction device inlet 6 to the ablation image 2 at the target surface 1 facilitates the removal of ablation debris from the target surface 2 as soon as the debris is projected from the target surface 2.

With particular reference to FIG. 2, which illustrates a view across the target surface 2 towards the extraction device inlet 6, the width x of the extraction device inlet 6 is configured to be at least 125% greater than the dimension y of the ablation image 2 at the target surface 1 in a direction perpendicular to said flow of insert gas across the target surface 1. This configuration serves to improve the uniformity of the flow of inert gas across the ablation image 2 at the target surface 1, particularly the uniformity of the velocity of the gas flow across the ablation image 2 at the target surface 1.

With particular reference to FIGS. 1 and 2, the extraction device inlet 6 adjacent to the ablation image 2 at the target surface 1 is configured to extend above the target surface 1 by a distance b at least 1.6 times than the height of the ablation plume created at the target surface 1. This configuration better prevents ablation debris particles escaping over the top edge of the extraction device inlet 6 and contaminating parts of the laser ablation apparatus, such as the projection lens 12.

The flow of inert gas from the gas nozzles 8 further helps to direct any ablation debris towards the extraction device inlet 6. With particular reference to FIG. 3, which illustrates a view across the target surface 2 towards the gas nozzles 8, the gas nozzles 8 are distributed over a distance greater than the above-discussed width y of the ablation image 2 at the target surface 1. The distribution of gas nozzles 8 includes nozzles 8a that direct gas over lateral edge portions 3 of the ablation image 2 at the target surface 1 towards the extraction device inlet 6, and yet further laterally outwardly positioned nozzles 8b. This nozzle distribution helps to ensure a uniform inert gas environment over the entire ablation image 2 at the target surface 1.

The inventors have found that the size of the lateral separation (dimension d in FIG. 1) of the extraction device inlet can affect the quality of the ablation image. In this embodiment of the invention, the lateral separation, d, is set to be in the range of about 1 mm to about 8 mm. It is thought that positioning the extraction device inlet 6 too close to the ablation image 2 can result in an excessively high concentration of ablated material over a portion of the ablation image 2 closest to the extraction device inlet 6, causing refraction of the laser beam in that region and decreasing the quality of the ablation image.

Also in this embodiment, the lower level of the extraction device inlet 6 is positioned about 2 mm (dimension e in FIG. 1) above the target surface, with the aim of preventing the extraction device inlet causing damage to the target surface.

Also, in this embodiment, the extraction device inlet 6 extends along only one side edge of the ablation image. However, in one variation, the extraction device inlet 6 further extends along two or more side edges of the ablation image.

Also, in this embodiment, the extraction device inlet 6 at the level of the ablation plume is used in combination with a flow of inert gas from gas nozzles positioned opposite to the extraction device inlet 6 across the target surface. However, in one variation, the extraction device inlet at the level of the ablation plume is used without such gas nozzles or any other means for providing a flow of inert gas across the target surface.

With reference to FIG. 4, the target surface 2 could, for example, be the surface of a semiconductor layer 40 that defines the semiconducting channels 44 between source and drain electrodes 42 of an array of TFTs for the backplane of a electrophoretic display device, wherein the ablation serves to remove selected portions of the semiconductor layer 40 between adjacent TFTs with the aim of reducing cross-talk between pixels of the display device.

In addition to any modifications explicitly mentioned above, it will be evident to a person skilled in the art that various other modifications of the described embodiment may be made within the scope of the invention.

1. A method, comprising: using a laser beam to ablate a target surface via a projection lens as part of a process of defining one or more elements of one or more electronic devices, wherein the ablating is performed whilst extracting material ablated from the target surface via an extraction device inlet having at least a portion at a level between said target surface and said projection lens and at the level of a plume of ablated material above said target surface.

2. The method according to claim 1, comprising: ablating said target surface whilst directing a flow of gas transversely across said target surface in a direction substantially parallel to the target surface from a gas outlet towards said extraction device inlet.

3. The method according to claim 2, wherein the gas outlet is arranged opposite to the extraction device inlet across the ablation image.

4. The method according to claim 2, wherein the extraction device inlet and the gas outlet are configured so as to achieve a substantially uniform gas flow velocity across the entire ablation image at the target surface.

5. The method according to claim 1, wherein the extraction device inlet extends in a direction perpendicular to the target surface to a height greater than the height of said plume.

6. The method according to claim 5, wherein the extraction device inlet extends in a direction perpendicular to the target surface to a height at least 1.6 times greater than the height of said plume.

7. The method according to claim 2, wherein the gas outlet includes an array of gas nozzles distributed over a distance greater than the distance to which said ablation image at the target surface extends in a direction perpendicular to said flow of gas.

8. The method according to claim 1, wherein the extraction device inlet has at least a portion no less than about 10 mm from the ablation image in a direction parallel to the target surface.

9. The method according to claim 1, wherein the extraction device inlet has a bottom edge located no less than about 2 mm above the target surface in a direction perpendicular to the target surface.
